(19) United States
(12) Patent Application Publication
(10) Pub. No.: US 2023/0125858 A1
(43) Pub. Date: Apr. 27, 2023

(54) ELECTRICAL OUTLET BOARD

(71) Applicant: Group Dekko, Inc., Fort Wayne, IN (US)

(72) Inventors: Raymond H. Riner, Fort Wayne, IN (US); Brian K. Rupert, Kendallville, IN (US)

(73) Assignee: Group Dekko, Inc., Fort Wayne, IN (US)

(21) Appl. No.: 17/509,660

(22) Filed: Oct. 25, 2021

(51) Int. Cl. H01R 25/00; H05K 1/18

(52) U.S. Cl. CPC H01R 25/006; H05K 1/18; H01R 12/58

(57) ABSTRACT

A tower system including a column and an electrical power outlet board positioned within the column, the electrical power outlet board having electrical power receptacles positioned on opposite sides of the board, the receptacles being accessible on opposite sides of the column.

### BACKGROUND OF THE INVENTION

### 1. Field of the Invention

The present invention relates to an electrical outlet board having multiple outlets.

### 2. Description of the Related Art

An electrical receptacle is arranged to receive an electrical plug, which is a movable connector attached to an electrically operated device. The receptacle is typically fixed on equipment or affixed to some building structure and is connected to an energized electrical circuit. The electrical receptacle sometimes also referred to as a socket may be surrounded by a decorative or protective cover, which may be integral with the receptacle.

Single-phase electrical receptacles have two current-carrying connections to the power supply circuit and may also have a third pin for a safety connection to earth ground. Electrical receptacles are often provided in pairs with such an arrangement being referred to as a duplex electrical outlet.

Electrical power strips are often used to power office equipment on or around office furniture. Such power strips generally have more than two electrical receptacles along a surface of the power strip. Plugs of equipment are then plugged into the power strip.

Tables and trays exist in the earliest records of mankind. Elevated flat surfaces that provide a natural utility to the user are needed for a variety of purposes and as such have developed into numerously varied items. For example, desks, nightstands, chests of drawers, counter tops, end tables, TV trays, to name a few, all have flat upper surfaces.

In public areas, such as parks, a pedestal table can be provided having a single column support that is embedded in the ground, or in a suitable ballast to prevent movement, with a tabletop mounted to the top of the single column. A movable version is often used in reception areas in the form of small tabletops arranged at a height that allow easy use for the setting of drinks or food thereon, while people stand therearound, allowing people to congregate around for collaboration and socialization.

In each case the tables lack integrated electrical and charging circuits to power devices in common use today.

What is needed in the art is a cost-effective system that allows for the delivery of electrical power.

### SUMMARY OF THE INVENTION

The present invention provides a back-to-back electrical power outlet board.

The invention in one form is directed to a tower system including a column and an electrical power outlet board positioned within the column, the electrical power outlet board having electrical power receptacles positioned on opposite sides of the board, the receptacles being accessible on opposite sides of the column.

The invention in another form is directed to an electrical distribution system insertable into a column, the system including a plurality of electrical power receptacles and an electrical power outlet board having the electrical power receptacles positioned on opposite sides of the board, the electrical power receptacles positionable for access through openings on opposite sides of the column.

The invention in yet another form is directed to a method of presenting electrical receptacles at openings in a column, the method including the steps of: connecting at least one electrical power receptacle to each side of an electrical power board; and staggering the electrical power receptacles from each other on the opposite sides of the electrical power board.

An advantage of the present invention presents electrical outlets on both sides of a printed circuit board.

Another advantage of the present invention is that the board can be fitted to a tight constrained place, such as inside a tube.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 is a perspective view of an embodiment of a tower tray system;

FIG. 2 is a side view of the tower tray system of FIG. 1;

FIG. 3 is a perspective view of an embodiment of a back-to-back electrical outlet board of the present invention that is used in the tower tray system of FIGS. 1 and 2;

FIG. 4 is a front view of the back-to-back electrical outlet board of FIG. 3;

FIG. 5 is a back view of the back-to-back electrical outlet board of FIGS. 3 and 4;

FIG. 6 is a right view of the back-to-back electrical outlet board of FIGS. 3-5;

FIG. 7 is a left view of the back-to-back electrical outlet board of FIGS. 3-6;

FIG. 8 is a top view of the back-to-back electrical outlet board of FIGS. 3-7; and

FIG. 9 is a bottom view of the back-to-back electrical outlet board of FIGS. 3-8.

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

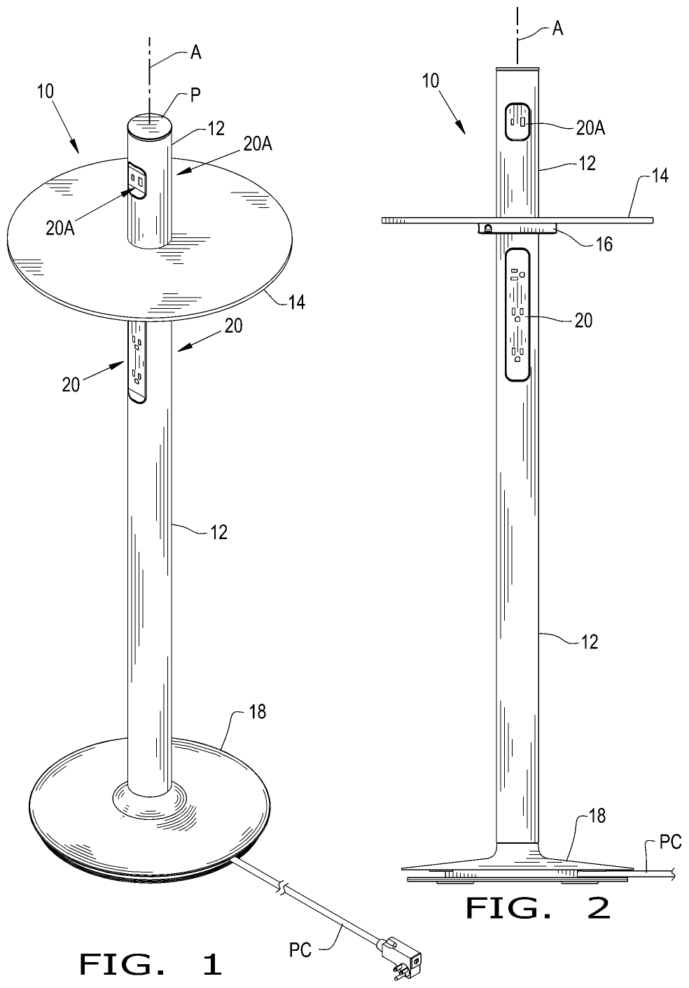

Referring now to the drawings, and more particularly to FIGS. 1 and 2, there is shown an embodiment of a tower system 10 including a column 12, a tray 14, a tray collar 16, a base 18, a set of outlets 20, and a set of outlets 20A. Tray collar 16 can also be referred to as a tray clamp 16. Tray column 12 may be a cylindrical tube 12 having electrical and data connections presented along the sides that are connected to electrical conductors that run therein. Tray 14 is illustrated as a disk-shaped tray 14, although other shapes are also contemplated. Tray 14 has an opening 24 though which column 12 extends. Tower system 10 is generally symmetrical along axis A in that outlets 20 and 20A are present on each side of column 12, although the positioning of the individual receptacles are offset in the longitudinal direction along axis A, for reasons discussed herein.

Base 18 is arranged to set on a horizontal surface and provides support to column 12. Base 18 is formed to allow an electrical power cord PC to extend therefrom and have an opening through which electrical wiring can extend into column 12. Column 12 is depicted as a cylindrical tube 12, although other shapes are contemplated. Column 12 provides a wiring chase through which internal wiring is provided for the powering of outlets 20 and charging circuits that may be made available at outlets 20A. Slots are cut or formed along sides of column 12 to allow power fixtures such as outlets 20 and 20A that are presented to, and are available for, use by the user of tower tray system 10. Outlets 20 and 20A are presented on both sides of column 12, even though only one side is illustrated.

Outlets 20 and 20A have cover plates that conform with edges in the slots in column 12, so that edges of that slot are covered. The ends of the cover plates extend along the curve created by the curved ends of the slot, as seen in in FIG. 1, and the curve of the surface of column 12. The placing of outlets 20 and 20A along surfaces of column 12 are a mater of choice and can be at various positions along the length of column 12. A top plate P can be inserted at the top of column 12 to provide a finished look, and top plate P can be removed to provide access to the interior of column 12.

Tray collar 16 is constrained against column 12, with collar 16 being under tension, hence compressing collar 16 against column 12 to thereby prevent the movement of collar 16 relative to column 12. This allows tray 14 to rest upon tray collar 16.

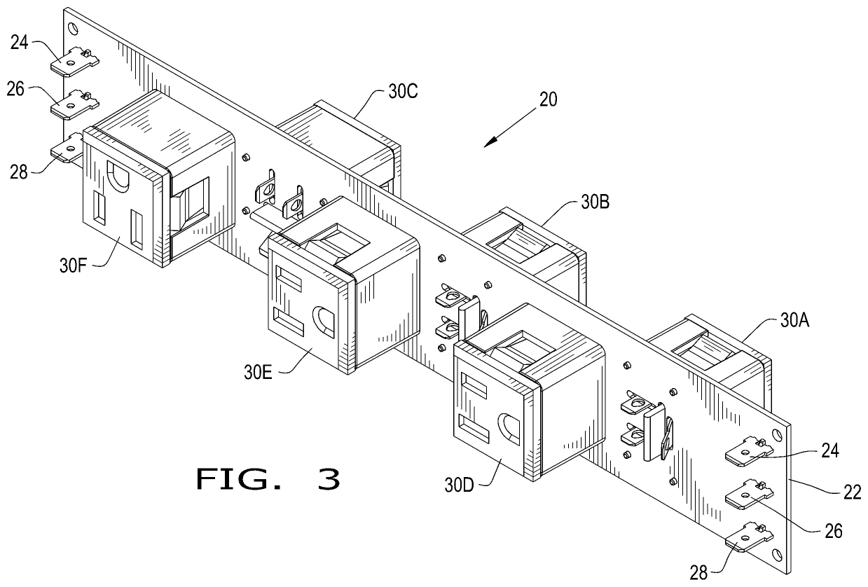

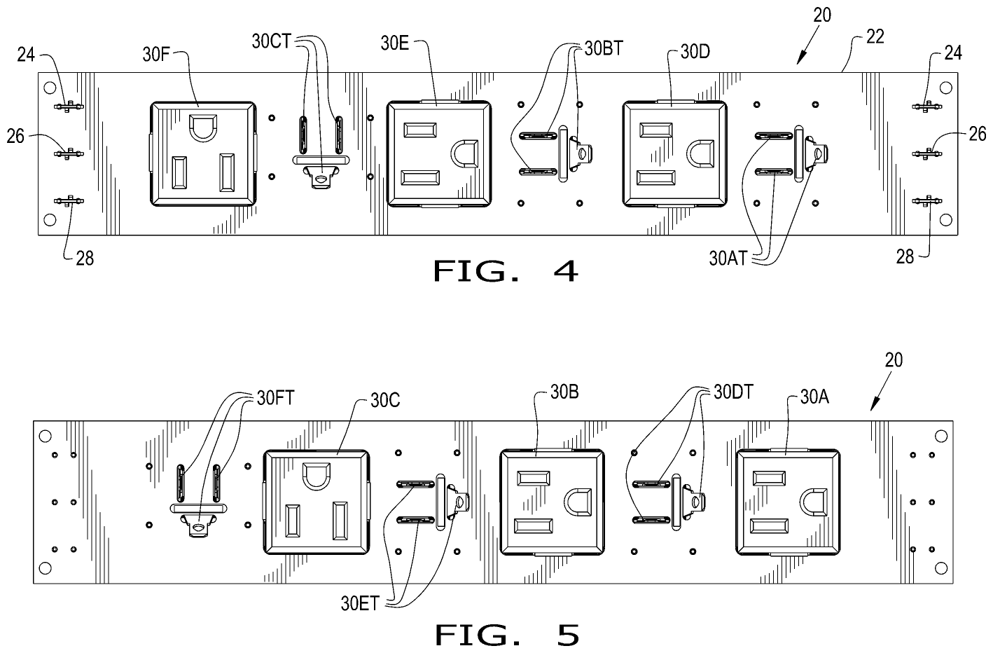

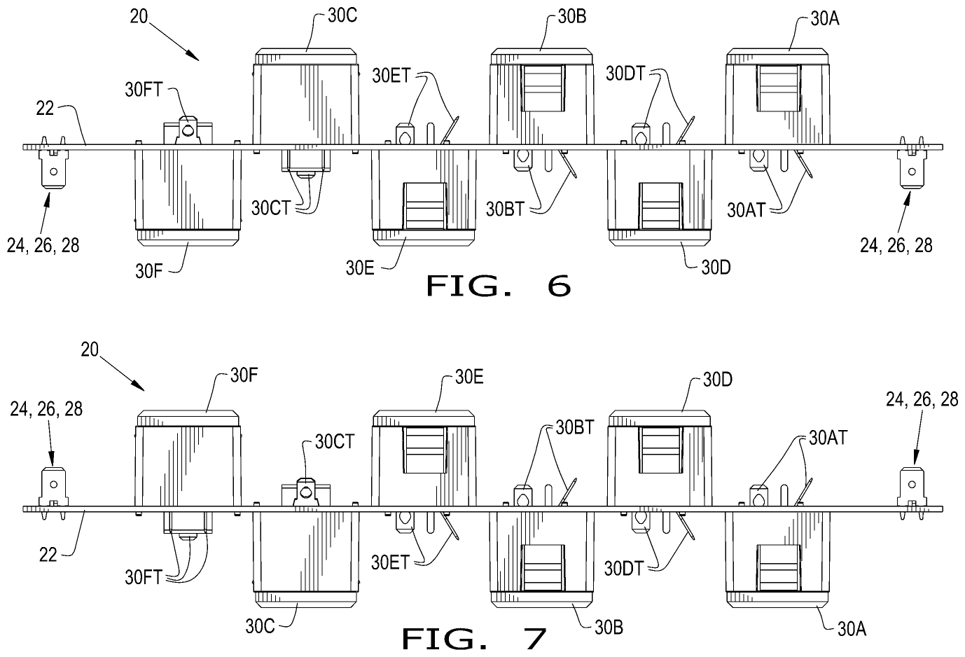

Now, additionally referring to FIGS. 3-9, there are shown more details of electrical power outlet board 20, which can also be referred to as electrical distribution system 20. Outlet board 20A, may also have some or all of the features of outlet board 20. System 20 includes a printed circuit board 22 having terminals 24, 26 and 28, and receptacles 30A, 30B, 30C, 30D, 30E, and 30F, half mounted on one side of printed circuit board 22 and the other half mounted on the other side of printed circuit board 22. As can be seen receptacles 30A, 30B, 30C, 30D, 30E, and 30F are arranged in a staggered configuration to allow for soldering connections to be made and to allow for a compact overall thickness of power outlet board 20. Also illustrated is that the orientation of receptacles 30A, 30B, 30C, 30D, 30E, and 30F can vary, as in the slot orientation of receptacle 30F versus receptacle 30E.

Terminals 30AT, 30BT, 30CT, 30DT, 30ET, and 30FT respectively extend from receptacles 30A, 30B, 30C, 30D, 30E, and 30F and extend through printed circuit board 22. Printed circuit board 22 has electrical power conduction paths thereon that connect the electrical power, electrical neutral and electrical ground to each of receptacles 30A, 30B, 30C, 30D, 30E, and 30F; and to terminals 24, 26 and 28. Terminals 24, 26 and 28 allow for slide on wiring terminations on each end of printed circuit board 22, which allows the conductors of power cord PC to be connected to one end of printed circuit board 22 and terminals 24, 26 and 28 on the other end of printed circuit board 22 allow for the connection of conductors to convey electrical power to outlet board 20A.

Printed circuit board 22 is a laminated sandwich structure of insulating layers with conductive pathways or traces therebetween. The conductive traces carryout the electrical conductance that is needed for the receptacles 30A, 30B, 30C, 30D, 30E, and 30F and terminals 24, 26 and 28 to be electrically connected and to function. Printed circuit board 22 has at least two complementary functions. The first is to position and fix electronic components at designated locations on the outer layer by soldering receptacles 30A, 30B, 30C, 30D, 30E, and 30F; and terminals 24, 26 and 28 thereto. The second is to provide the electrical pathways and connections, as well as electrically isolate the pathways from each other. The electrical traces that are positioned between or on the insulating layers provides the electrical connections in the layer while feedthroughs are made by drilling precisely located holes through printed circuit board 22 and then plating the holes with copper. The feedthroughs are the electrical interconnections between the insulating layers in the laminate structure. This construct allows for a three-dimensional connection between the layers in a controlled manner that is both reliable and cost-effective for placing receptacles 30A, 30B, 30C, 30D, 30E, and 30F; and terminals 24, 26 and 28 in the desired locations. Advantageously, power outlet board 20 provides a compact assembly for the number of receptacles in the orientation they are in on a compact board. Another advantage of printed circuit board 22 is that it also insulates the conductive surfaces from moisture that could result in conductivity issues.

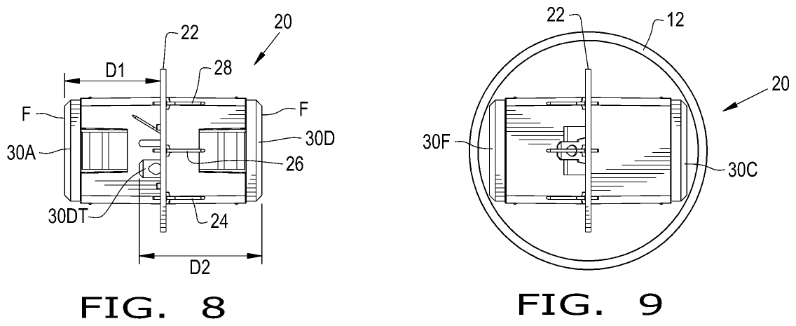

In FIG. 8, distances D1 and D2 are illustrated, with distance D1 being a distance from a face F of a receptacle (here receptacle 30A) to a surface of printed circuit board 22, and distance D2 being the distance from the face F of a receptacle (here receptacle 30D) to the extent of terminals 30DT. This illustrates that a distance from face F to face F of receptacles on opposite sides of printed circuit board 22 is approximately 2×D1, which is clearly less than 2×D2. This arrangement allows system 20 to fit inside column 12 as illustrated in FIG. 9, in which the inside diameter of column 12 is less than 2×D2 and greater than 2×D1.

Receptacles 30A, 30B, 30C, 30D, 30E, and 30F have a face F and a height D2, the face F being oriented parallel to and outwardly away from electrical power outlet board 20. Height D2 is a distance from face F to an end of the terminals 30AT, 30BT, 30CT, 30DT, 30ET, 30FT, the height D2 being greater than distance D1 from the electrical power outlet board 22 to face F. Distance D1 from the face F of the electrical power receptacle on one side of the electrical power outlet board 22 to the face F of the electrical power receptacle 30A, 30B, 30C, 30D, 30E, and 30F on the opposite side of the electrical power outlet board 22 is less than twice the height D2.

Electrical wiring that supplies power to electrical outlets 20 and charging outlet 22 are contained within column 12. Power cord PC exits from base 18 and is connected to power electrical distribution system 20. It is also contemplated that electrical power could alternatively be supplied through an opening in the top of column 12. Although tower tray system 10 has been illustrated as being configured to set on a horizontal surface, it is also contemplated that another embodiment of tower tray system 10 would extend from a floor to a ceiling. Further it is also contemplated that a tower tray system 10 could be suspended from a ceiling or another horizontal structure in a room.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A tower system, comprising:
a column; and
an electrical power outlet board positioned within the column, the electrical power outlet board having electrical power receptacles positioned on opposite sides of the board, the receptacles being accessible on opposite sides of the column.

2. The tower system of claim 1, wherein the electrical power receptacles are staggered from each other on the opposite sides.

3. The tower system of claim 2, wherein the electrical power outlet board is a printed circuit board.

4. The tower system of claim 2, wherein the electrical power receptacles have a face and a height, the face being oriented parallel to and outwardly away from the electrical power outlet board.

5. The tower system of claim 4, wherein the electrical power receptacles have terminals extending from a side opposite the face, the height is a distance from the face to an end of the terminals, the height being greater than a distance from the electrical power outlet board to the face.

6. The tower system of claim 5, wherein a distance from the face of the electrical power receptacle on one side of the electrical power outlet board to the face of the electrical power receptacle on the opposite side of the electrical power outlet board is less than twice the height.

7. The tower system of claim 6, wherein the electrical power receptacles include a plurality of electrical power receptacles on each side of the electrical power outlet board.

8. The tower system of claim 1, further comprising a tray having an opening through which the column extends.

9. An electrical distribution system insertable into a column, the system comprising:
a plurality of electrical power receptacles; and
an electrical power outlet board having the electrical power receptacles positioned on opposite sides of the board, the electrical power receptacles positionable for access through openings on opposite sides of the column.

10. The electrical distribution system of claim 9, wherein the electrical power receptacles are staggered from each other on the opposite sides.

11. The electrical distribution system of claim 10, wherein the electrical power outlet board is a printed circuit board.

12. The electrical distribution system of claim 10, wherein the electrical power receptacles have a face and a height, the face being oriented parallel to and outwardly away from the electrical power outlet board.

13. The electrical distribution system of claim 12, wherein the electrical power receptacles have terminals extending from a side opposite the face, the height is a distance from the face to an end of the terminals, the height being greater than a distance from the electrical power outlet board to the face.

14. The electrical distribution system of claim 13, wherein a distance from the face of the electrical power receptacle on one side of the electrical power outlet board to the face of the electrical power receptacle on the opposite side of the electrical power outlet board is less than twice the height.

15. The electrical distribution system of claim 14, wherein the electrical power receptacles include a plurality of electrical power receptacles on each side of the electrical power outlet board.

16. A method of presenting electrical receptacles at openings in a column, the method comprising the steps of:
connecting at least one electrical power receptacle to each side of an electrical power board; and
staggering the electrical power receptacles from each other on the opposite sides of the electrical power board.

17. The method of claim 16, wherein the electrical power receptacles have a face and a height, the face being oriented parallel to and outwardly away from the electrical power outlet board.

18. The method of claim 17, wherein the electrical power receptacles have terminals extending from a side opposite the face, the height is a distance from the face to an end of the terminals, the height being greater than a distance from the electrical power outlet board to the face.

19. The method of claim 18, wherein a distance from the face of the electrical power receptacle on one side of the electrical power outlet board to the face of the electrical power receptacle on the opposite side of the electrical power outlet board is less than twice the height.

20. The method of claim 19, wherein the electrical power receptacles include a plurality of electrical power receptacles on each side of the electrical power outlet board.
